(19) United States
(12) Patent Application Publication
(10) Pub. No.: US 2019/0109276 A1
(43) Pub. Date: Apr. 11, 2019

(54) MAGNETORESISTIVE ELEMENT, MEMORY ELEMENT, AND ELECTRONIC APPARATUS

(71) Applicant: SONY CORPORATION, Tokyo (JP)

(72) Inventors: Hiroyuki UCHIDA, Kanagawa (JP); Masanori HOSOMI, Tokyo (JP); Hiroyuki OHMORI, Kanagawa (JP); Kazuhiro BESSHO, Kanagawa (JP); Yutaka HIGO, Kanagawa (JP)

(73) Assignee: SONY CORPORATION, Tokyo (JP)

(21) Appl. No.: 16/087,206

(22) PCT Filed: Feb. 21, 2017
(86) PCT No.: PCT/JP2017/006260

§ 371 Date: Sep. 21, 2018

(30) Foreign Application Priority Data
Mar. 30, 2016 (JP) 2016-067324

(51) Int. Cl. H01L 43/02; G11C 11/16; H01F 10/32; H01L 43/10; H01L 27/22

(52) U.S. Cl. CPC H01L 43/02; G11C 11/161; H01F 10/3259; H01F 10/329; H01L 27/228; H01F 10/3286; H01L 43/10

(57) ABSTRACT

Provided is a magnetoresistive element including: a storage layer of which a magnetization direction changes in accordance with information; a first magnetization fixed layer below the storage layer having a magnetization direction perpendicular to a film surface; a second magnetization fixed layer above the storage layer having a magnetization direction that is perpendicular to the film surface and that is opposite to the magnetization direction of the first magnetization fixed layer; a first intermediate layer between the first magnetization fixed layer and the storage layer; and a second intermediate layer between the second magnetization fixed layer and the storage layer. The storage layer includes a first magnetic material layer, a non-magnetic material layer, and a second magnetic material layer laminated in that order, and one of the first magnetic material layer and the second magnetic material layer has a magnetization direction parallel to the film surface.

### TECHNICAL FIELD

The present disclosure relates to a magnetoresistive element, a memory element, and an electronic apparatus.

### BACKGROUND ART

The amount of information handled by various electronic apparatuses has been explosively increasing with the progress of information society in recent years. Thus, storage devices used in such electronic apparatuses are required to have further improved performance.

Among the devices, as substitutes for storage devices such as NOR flash memories or DRAMs that are generally used at present, magnetic random access memories (MRAMs), particularly, magnetic random access memories (MRAMs) (or spin torque-magnetic random access memories (ST-MRAMs)) that use spin torque magnetization reversal (which is also called spin injection magnetization reversal), have gained attention. The ST-MRAMs are considered to be capable of realizing low power consumption and large capacity while maintaining advantages of MRAMs which are operations at high speeds and a substantially indefinite number of rewriting operations.

Although an ST-MRAM is configured such that a plurality of memory cells, each including a magnetoresistive element serving as a storage element that stores information of 1/0 are arrayed therein, an element having a magnetic tunnel junction (MTJ) structure has been used as the magnetoresistive element. The MTJ structure is a structure in which a non-magnetic material layer (a tunnel barrier layer) is sandwiched between two magnetic material layers (a magnetization fixed layer and a storage layer). A magnetoresistive element with the MTJ structure will also be referred to as an MTJ element hereinbelow. In an MTJ element, information of 1/0 is recorded by using spin torque magnetization reversal in the storage layer generated by causing a current to flow in the MTJ structure.

Here, a dual MTJ structure of an MTJ element in which magnetization fixed layers are respectively arranged both above and below a storage layer having tunnel barrier layers interposed therebetween has been proposed. According to the dual MTJ structure, spin torque is supplied by the two magnetization fixed layers from both above and below the storage layer, and thus an effect of reducing a current necessary for spin torque magnetization reversal (reverse current) in a magnetoresistive element is expected. That is, by configuring an ST-MRAM with such a magnetoresistive element having the dual MTJ structure, lower power consumption can be achieved.

As a magnetoresistive element having the dual MTJ structure, for example, one disclosed in Patent Literature 1 has been proposed. Specifically, Patent Literature 1 proposes a magnetoresistive element having the dual MTJ structure in which a film thickness of a the tunnel barrier layer arranged on the upper side among two tunnel barrier layers is greater than a film thickness of the tunnel barrier layer arranged on the upper side. According to the magnetoresistive element disclosed in Patent Literature 1, by configuring the film thicknesses of the two tunnel barrier layers as described above, a magnetoresistance change ratio (MR ratio) can be increased.

### CITATION LIST

### Patent Literature

Patent Literature 1: JP 2014-49766A

### DISCLOSURE OF INVENTION

### Technical Problem

However, in the technology disclosed in Patent Literature 1, the upper tunnel barrier layer is formed to have a relatively thin film thickness. When the film thickness of the tunnel barrier layer is thin, a withstand voltage of the magnetoresistive element decreases, and thus there is a possibility of reliability of the element being significantly impaired.

Taking the above-described circumstance into account, a technology that can further increase a magnetoresistance change ratio of a magnetoresistive element without impairing reliability thereof has been demanded. Therefore, the present disclosure proposes a novel and improved magnetoresistive element, memory element, and electronic apparatus that can further increase a magnetoresistance change ratio without impairing reliability.

### Solution to Problem

According to the present disclosure, there is provided a magnetoresistive element including: a storage layer of which a magnetization direction is configured to change in accordance with information; a first magnetization fixed layer configured to be provided below the storage layer and have a magnetization direction perpendicular to a film surface serving as a reference of information stored in the storage layer; a second magnetization fixed layer configured to be provided above the storage layer and have a magnetization direction that is perpendicular to the film surface serving as a reference of information stored in the storage layer and is opposite to the magnetization direction of the first magnetization fixed layer; a first intermediate layer configured to be provided between the first magnetization fixed layer and the storage layer; and a second intermediate layer configured to be provided between the second magnetization fixed layer and the storage layer. The storage layer includes a first magnetic material layer, a non-magnetic material layer, and a second magnetic material layer laminated in that order, and one of the first magnetic material layer and the second magnetic material layer has a magnetization direction parallel to the film surface.

In addition, according to the present disclosure, there is provided a memory element including: a plurality of magnetoresistive elements configured to retain information in accordance with a magnetization state of a magnetic material; and wiring configured to apply a current to each of the plurality of magnetoresistive elements in a laminating direction or detect a current flowing in each of the plurality of magnetoresistive elements in the laminating direction. Each of the magnetoresistive elements includes a storage layer of which a magnetization direction is configured to change in accordance with information, a first magnetization fixed layer configured to be provided below the storage layer and have a magnetization direction perpendicular to a film surface serving as a reference of information stored in the storage layer, a second magnetization fixed layer configured to be provided above the storage layer and have a magnetization direction that is perpendicular to the film surface serving as a reference of information stored in the storage layer and is opposite to the magnetization direction of the first magnetization fixed layer, a first intermediate layer configured to be provided between the first magnetization fixed layer and the storage layer, and a second intermediate layer configured to be provided between the second magnetization fixed layer and the storage layer, the storage layer includes a first magnetic material layer, a non-magnetic material layer, and a second magnetic material layer laminated in that order, and one of the first magnetic material layer and the second magnetic material layer has a magnetization direction parallel to the film surface.

In addition, according to the present disclosure, there is provided an electronic apparatus including: a memory element configured to store information. The memory element includes a plurality of magnetoresistive elements configured to retain information in accordance with a magnetization state of a magnetic material, and wiring configured to apply a current to each of the plurality of magnetoresistive elements in a laminating direction or detect a current flowing in each of the plurality of magnetoresistive elements in the laminating direction, each of the magnetoresistive elements includes a storage layer of which a magnetization direction is configured to change in accordance with information, a first magnetization fixed layer configured to be provided below the storage layer and have a magnetization direction perpendicular to a film surface serving as a reference of information stored in the storage layer, a second magnetization fixed layer configured to be provided above the storage layer and have a magnetization direction that is perpendicular to the film surface serving as a reference of information stored in the storage layer and is opposite to the magnetization direction of the first magnetization fixed layer, a first intermediate layer configured to be provided between the first magnetization fixed layer and the storage layer, and a second intermediate layer configured to be provided between the second magnetization fixed layer and the storage layer, the storage layer includes a first magnetic material layer, a non-magnetic material layer, and a second magnetic material layer laminated in that order, and one of the first magnetic material layer and the second magnetic material layer has a magnetization direction parallel to the film surface.

According to the present disclosure, in a so-called perpendicular magnetization-type magnetoresistive element having the dual MTJ structure, a storage layer is configured by laminating a first magnetic material layer, a non-magnetic material layer, and a second magnetic material layer. In addition, a magnetization direction of at least one of the first magnetic material layer and the second magnetic material layer is set to an in-plane direction. Accordingly, a TMR effect of a tunnel barrier layer coming in contact with the magnetic material layer of which the magnetization direction is oriented in the in-plane direction can be reduced. Thus, a magnetoresistance change ratio of the whole element can be improved. At this time, without thinning a film thickness of the tunnel barrier layer, the TMR effect can be reduced, and therefore reliability of the element can also be ensured.

### Advantageous Effects of Invention

According to the present disclosure described above, it is possible to further increase a magnetoresistance change ratio without impairing reliability. Note that the effects described above are not necessarily limitative. With or in the place of the above effects, there may be achieved any one of the effects described in this specification or other effects that may be grasped from this specification.

### BRIEF DESCRIPTION OF DRAWINGS

FIG. 1 is a diagram schematically illustrating a cross-section of a general vertical magnetization-type magnetoresistive element.

FIG. 2 is a diagram for describing a tunnel magnetoresistance effect of the general magnetoresistive element illustrated in FIG. 1.

FIG. 3 is a diagram schematically illustrating a cross-section of a magnetoresistive element having a general dual MTJ structure.

FIG. 4 is a diagram for describing a TMR effect of a magnetoresistive element 321 having the general dual MTJ structure.

FIG. 5 is a perspective view illustrating a schematic configuration of a storage device according to an embodiment of the present disclosure.

FIG. 6 is a cross-sectional view illustrating a schematic configuration of a magnetoresistive element according to the present embodiment illustrated in FIG. 5.

FIG. 7 is a cross-sectional view illustrating an enlarged lower tunnel barrier layer, storage layer, and upper tunnel barrier layer extracted from the magnetoresistive element according to the present embodiment illustrated in FIG. 6.

FIG. 8 is a graph illustrating measurement results of magnetization curves of a storage layer of sample 1.

FIG. 9 is a graph illustrating measurement results of magnetization curves of a storage layer of sample 2.

FIG. 10 is a graph illustrating measurement results of magnetization curves of a storage layer of sample 3.

### MODE(S) FOR CARRYING OUT THE INVENTION

Hereinafter, (a) preferred embodiment(s) of the present disclosure will be described in detail with reference to the appended drawings. Note that, in this specification and the appended drawings, structural elements that have substantially the same function and structure are denoted with the same reference numerals, and repeated explanation of these structural elements is omitted.

Note that description will be provided in the following order.

1. Background to present disclosure
2. Configuration of storage device
3. Structure of magnetoresistive element

### 4. Supplement

In addition, when a magnetization direction or magnetic anisotropy is described in the present specification, terms such as a “perpendicular direction” (a direction perpendicular to a film surface), an “in-plane direction” (a direction parallel to a film surface), and the like are used for the sake of convenience. However, these terms do not necessarily mean exact directions of magnetization. For example, wordings such as “a magnetization direction is a perpendicular direction,” “having perpendicular magnetic anisotropy,” and the like mean that magnetization in a perpendicular direction is a dominant state over magnetization in an in-plane direction. Likewise, for example, wordings such as “a magnetization direction is an in-plane direction,” “having in-plane magnetic anisotropy,” and the like mean that magnetization in the in-plane direction is a dominant state over magnetization in a perpendicular direction.

### (1. Background to Present Disclosure)

The background to the present disclosure achieved by the present inventors will be described before describing preferred embodiments of the present disclosure to further clarify effects of the present invention.

Along with the rapid development of various kinds of information apparatuses beginning from large capacity servers to mobile terminals, even higher performance including high integration, high speed, low power consumption, and the like has been sought for storage devices such as memories constituting the apparatuses. Particularly, progress of semiconductor non-volatile memories has been remarkable, and flash memories have become widespread as centralized large capacity file memories with the momentum to drive out hard disk drives. Meanwhile, in view of expansion into memories for code storage and further into working memories, development of ferroelectric random access memories (FeRAMs), MRAMs, phase-change random access memories (PCRAMs), and the like as storage devices that can replace NOR flash memories, DRAMs, and the like that are generally used at present, is underway, and some such memories have already been put to practical use.

Among these, MRAMs store information using a magnetization direction of a magnetic material, thus can perform a substantially infinite number of (10¹⁵ or more) rewriting operations at high speeds, and therefore have already been used in the fields of industrial automation, aviation, and the like. MRAMs are expected to expand into code storages and working memories in the future due to their high-speed operations and reliability; however in reality, they have problems of low power consumption and high capacities. These are fundamental problems attributable to the recording principle of MRAMs, that is, the method of reversing magnetization using a current magnetic field generated from wiring. As one method for solving these problems, recording methods that are not dependent on a current magnetic field, that is, magnetization reversal methods, have been studied, and among these, spin torque magnetization reversal is being actively researched and developed.

In an MRAM (ST-MRAM) using spin torque magnetization reversal, a magnetoresistive element that functions as a storage element storing information of 1/0 is configured as an MTJ element having an MTJ structure. The MTJ structure has a configuration in which a tunnel barrier layer is sandwiched between a magnetic material layer of which a magnetization direction is fixed in a certain direction (magnetization fixed layer) and another magnetic material layer of which a magnetization direction is free (the magnetization direction is not fixed) (storage layer). It is known with respect to the MTJ structure that, by causing a current to flow in the MTJ structure, torque is given to the storage layer when spin-polarized electrons that have passed through the magnetization fixed layer enter the storage layer, and then a phenomenon of reversal of a magnetization direction of the storage layer takes place. An MTJ element performs recording of information using this phenomenon by causing a current having a value equal to or higher than a certain threshold value to flow therein to reverse a magnetization direction of the storage layer. In addition, at this time, rewriting of 1/0 is performed by changing the polarity of the current.

In an MTJ element, the absolute value of a current necessary for the reversal of a magnetization direction of a storage layer (reverse current) is equal to or lower than 1 mA for an element with a scale of about 0.1 um, and since the current value decreases in proportion to the element volume, scaling is possible. Moreover, since a word line for generating a recording current magnetic field necessary in conventional MRAMs, which do not utilize spin torque magnetization reversal, is unnecessary, ST-MRAMs have an advantage of a simple cell structure. For those reasons, ST-MRAMs are highly anticipated as non-volatile memories that can achieve low power consumption and high capacities while maintaining the advantages of MRAMs including a high speed and a substantially infinite number of rewriting operations.

Although various materials have been examined as magnetic materials to be used in magnetoresistive elements that constitute ST-MRAMs, materials having perpendicular magnetic anisotropy rather than those having in-plane magnetic anisotropy are generally deemed to be suitable for low power consumption and large capacities. The reason for this is that perpendicular magnetization has a lower energy barrier to overcome during spin torque magnetization reversal, and high magnetic anisotropy of a perpendicular magnetization film is advantageous for retaining thermal stability of a miniaturized storage carrier by increasing a capacity.

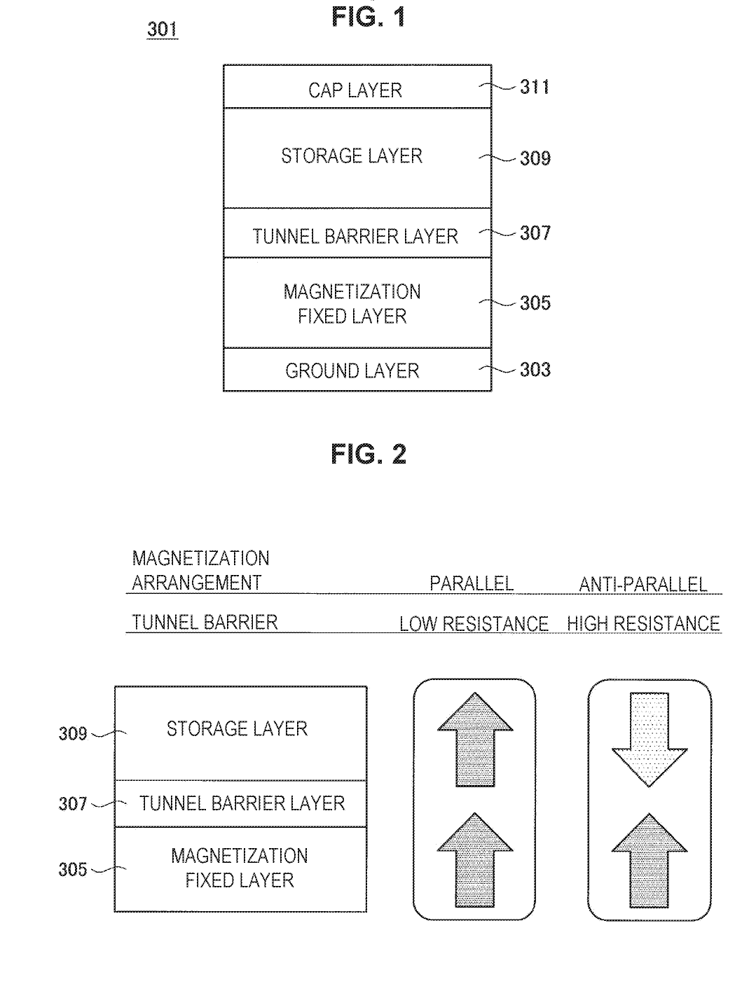

A structure of a general magnetoresistive element constituted by magnetic materials having perpendicular magnetic anisotropy (perpendicular magnetization-type magnetoresistive element) will be described with reference to FIG. 1. FIG. 1 is a diagram schematically illustrating a cross-section of a general perpendicular magnetization-type magnetoresistive element.

As illustrated, a perpendicular magnetization-type magnetoresistive element 301 is configured in the MTJ structure in which, on a ground layer 303, a magnetization fixed layer 305 that is a magnetic material layer having perpendicular magnetic anisotropy of which a magnetization direction is fixed in one direction due to a strong coercive force, a tunnel barrier layer 307 including a non-magnetic material, and a storage layer 309 that is a magnetic material layer having perpendicular magnetic anisotropy of which a magnetization direction is free are laminated. In addition, a cap layer 311 is laminated on the storage layer 309.

Information recording (writing) in the magnetoresistive element 301 is performed by reversing a magnetization direction of the storage layer 309 having uniaxial anisotropy. Specifically, when information is written, a current is applied in a film surface perpendicular direction to cause spin torque magnetization reversal in the storage layer 309.

Here, spin torque magnetization reversal will be briefly described. Electrons have two types of spin angular momentum. The two types are defined as upward and downward momentum. The numbers of electrons of both types are the same in a non-magnetic material, and different in a magnetic material. A case in which magnetization directions of the two magnetic material layers (i.e., the magnetization fixed layer 305 and the storage layer 309) of the magnetoresistive element 301 illustrated in FIG. 1 are opposite (an anti-parallel state) and electrons move from the magnetization fixed layer 305 that is a lower magnetic material layer to the storage layer 309 that is an upper magnetic material layer will be considered. In this case, spin polarization occurs in electrons that have passed through the magnetization fixed layer 305, that is, a difference is made between the number of electrons having upward spin angular momentum and the number of electrons having downward spin angular momentum.

When the electrons in this state pass through a non-magnetic material, the polarization is normally relaxed in the non-magnetic material, which results in a non-polarization state (a state in which the number of electrons having upward spin angular momentum is the same as the number of electrons having downward spin angular momentum). However, in a case in which a thickness of the tunnel barrier layer 307 that is a non-magnetic material layer is sufficiently thin, as in the magnetoresistive element 301, the electrons reach the other magnetic material, that is, the storage layer 309, before the polarization is relaxed and a non-polarization state is caused. In this case, the sign of a spin polarization degree is reversed, which lowers system energy, and thus some electrons are reversed, that is, caused to change the direction of spin angular momentum.

At this moment, since the total angular momentum of the system should be preserved, a reaction equivalent to the total change in the angular momentum by the electrons that have changed directions is also exerted on a magnetic moment of magnetism of the storage layer 309. In a case in which a current, that is, the number of electrons passing in a unit time, is small, a total number of electrons changing the direction of spin angular momentum also decreases, and thus the change in angular momentum generated in the magnetic moment of the storage layer 309 is small as well, but if the current increases, more change in angular momentum can be made within the unit time. A temporal change of angular momentum is torque, and when torque exceeds a certain threshold value, the magnetic moment of the storage layer 309 starts to reverse, a 180-degree rotation is made due to uniaxial anisotropy thereof, and then the storage layer becomes stable. Accordingly, in the magnetoresistive element 301, reversal from an anti-parallel state to a parallel state (i.e., a state in which the magnetization directions of the magnetization fixed layer 305 and the storage layer 309 are the same) occurs.

If a current is caused to flow in the opposite direction, that is, the direction in which electrons are sent from the storage layer 309 to the magnetization fixed layer 305, in the parallel state, the magnetization direction of the storage layer 309 is reversed this time due to torque given when spin-reversed electrons reflected in the magnetization fixed layer 305 enter the storage layer 309, which can reverse the state of the magnetoresistive element 301 to the anti-parallel state. However, at this moment, an amount of current necessary for causing reversal is larger than in a case in which reversal is performed from the anti-parallel state to the parallel state. Although reversal from the parallel state to the anti-parallel state is difficult to intuitively understand, it may be considered that, since a magnetization direction is fixed in the magnetization fixed layer 305, it is not possible to reverse the magnetization direction, and the magnetization direction is reversed in the storage layer 309 to preserve the angular momentum of the whole system.

FIG. 2 is a diagram for describing a tunnel magnetoresistance (TMR) effect of the general magnetoresistive element 301 illustrated in FIG. 1. In FIG. 2, only the magnetization fixed layer 305, the tunnel barrier layer 307, and the storage layer 309 of the magnetoresistive element 301 illustrated in FIG. 1 are illustrated, and magnetization directions of the magnetization fixed layer 305 and the storage layer 309 are simulatively indicated by upward and downward arrows beside the layers. As illustrated, in the magnetoresistive element 301, electric resistance of the tunnel barrier layer 307 becomes higher in the parallel state in which magnetization directions of the magnetization fixed layer 305 and the storage layer 309 are the same than in the anti-parallel state in which magnetization directions of both layers are different, and thus electric resistance of the whole element becomes higher.

In the magnetoresistive element 301, information of 1/0 is stored using such a difference in electric resistance. That is, in the magnetoresistive element 301, recording of information of 1/0 is performed by causing a current having a value equal to or higher than a certain threshold value corresponding to the polarity of each layer to flow in the direction from the magnetization fixed layer 305 to the storage layer 309 or the opposite direction.

Here, with respect to the perpendicular magnetization-type magnetoresistive element 301, when a reverse current for reversing from the parallel state to the anti-parallel state is assumed to be Ic_{—perp1} and a reverse current for reversing from the anti-parallel state to the parallel state is assumed to be Ic_{—perp2}, IC_{—perp1} and Ic_{—perp2} are represented by the following expressions (1) and (2), respectively.

$$\begin{matrix}[ Math . 1 ] & \\ {I}_{c \_ perp 1} = ( \frac{A \cdot α \cdot Ms \cdot V}{g ( 0 ) \cdot P} ) ( Hk - 4 π Ms ) & ( 1 ) \\ {I}_{c \_ perp 2} = - ( \frac{A \cdot α \cdot Ms \cdot V}{g ( π ) \cdot P} ) ( Hk - 4 π Ms ) & ( 2 )\end{matrix}$$

Meanwhile, with respect to an in-plane magnetization-type magnetoresistive element (a magnetoresistive element constituted by a magnetic material having in-plane magnetic anisotropy), when a reverse current for reversing from the parallel state to the anti-parallel state is assumed to be Ic_{—para1} and a reverse current for reversing from the anti-parallel state to the parallel state is assumed to be Ic_{—para2}, Ic_{—para1} and Ic_{—para2} are represented by the following expressions (3) and (4), respectively.

$$\begin{matrix}[ Math . 2 ] & \\ {I}_{c \_ para 1} = ( \frac{A \cdot α \cdot Ms \cdot V}{g ( 0 ) \cdot P} ) ( Hk + 2 π Ms ) & ( 3 ) \\ {I}_{c \_ para 2} = - ( \frac{A \cdot α \cdot Ms \cdot V}{g ( π ) \cdot P} ) ( Hk + 2 π Ms ) & ( 4 )\end{matrix}$$

Here, A represents a constant, α represents a damping constant, Ms represents saturation magnetization, V represents an element volume, g(0)P and g(π)P represent coefficients corresponding to efficiency at which spin torque is transmitted to the other magnetic material layer in the parallel state and the anti-parallel state, respectively, and Hk represents magnetic anisotropy (for more details of the above expressions (1) to (4), refer to, for example, “S. Mangin et al., Nature Materials, Vol. 5, March 2006, p. 210”).

In the above expressions (1) to (4), when the term (Hk-4πMs) appearing in the case of the perpendicular magnetization-type and the term (Hk+2πMs) appearing in the case of the in-plane magnetization type are compared, it can be ascertained that the perpendicular magnetization-type magnetoresistive element 301 can record information at lower reverse current than an in-plane magnetization-type magnetoresistive element, that is, the former is more suitable for a low recording current. For this reason, research and development regarding memories using perpendicular magnetization-type magnetoresistive elements as ST-MRAMs are being actively conducted.

With regard to an ST-MRAM using such a perpendicular magnetization-type magnetoresistive element, in order to realize higher densification of the memory element, it is necessary to reduce reverse currents and to further reduce the areas of the memory elements. Thus, as a structure for reducing a reverse current in MTJ elements, the dual MTJ structure in which magnetization fixed layers are arranged both above and below a storage layer having tunnel barrier layers interposed therebetween has been proposed.

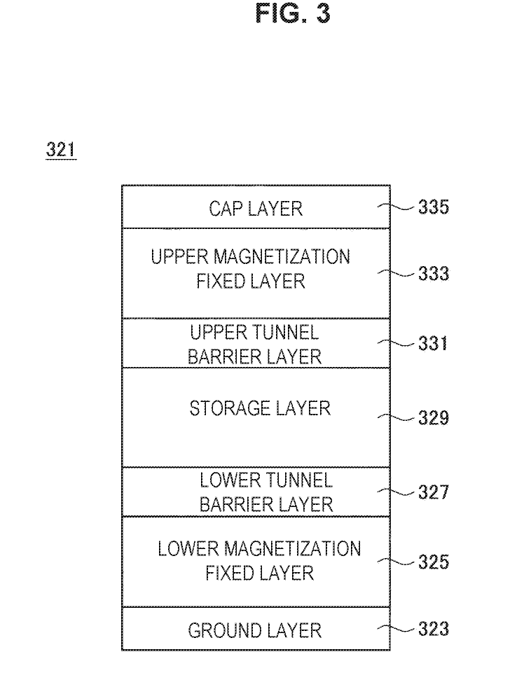

A structure of a magnetoresistive element having the general dual MTJ structure will be described with reference to FIG. 3. FIG. 3 is a diagram schematically illustrating a cross-section of a magnetoresistive element having the general dual MTJ structure.

As illustrated, the magnetoresistive element 321 having the dual MTJ structure is configured in the dual MTJ structure in which, on a ground layer 323, a lower magnetization fixed layer 325 that is a magnetic material layer having perpendicular magnetic anisotropy of which a magnetization direction is fixed in one direction, a lower tunnel barrier layer 327 including a non-magnetic material, a storage layer 329 that is a magnetic material layer having perpendicular magnetic anisotropy of which a magnetization direction is free, an upper tunnel barrier layer 331 including a non-magnetic material, and an upper magnetization fixed layer 333 that is a magnetic material layer having perpendicular magnetic anisotropy of which a magnetization direction is fixed in the opposite direction to that of the lower magnetization fixed layer 325 are laminated. In addition, a cap layer 335 is laminated on the upper magnetization fixed layer 333.

In the magnetoresistive element 321, by applying a current to the magnetoresistive element 321, the magnetization direction of the storage layer 329 is reversed and information is recorded, as in the magnetoresistive element 301 illustrated in FIG. 1. At this time, according to the dual MTJ structure, spin torque is supplied by the two magnetization fixed layers 325 and 333 from both above and below the storage layer 329, and thus a decrease in a reverse current and elimination of polar asymmetry in the magnetoresistive element 321 are expected.

However, since there are the two tunnel barrier layers 327 and 331 in the magnetoresistive element 321 having the dual MTJ structure, the TMR effect in the tunnel barrier layers 327 and 331 is offset, and thus there is concern of an electric resistance change of a whole element decreasing, that is, a magnetoresistance change ratio being lowered.

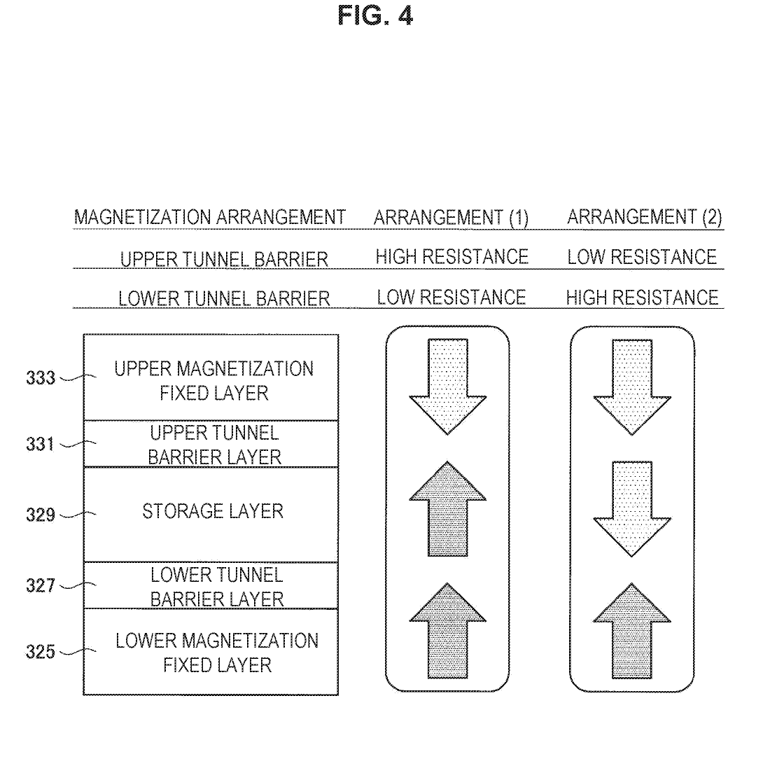

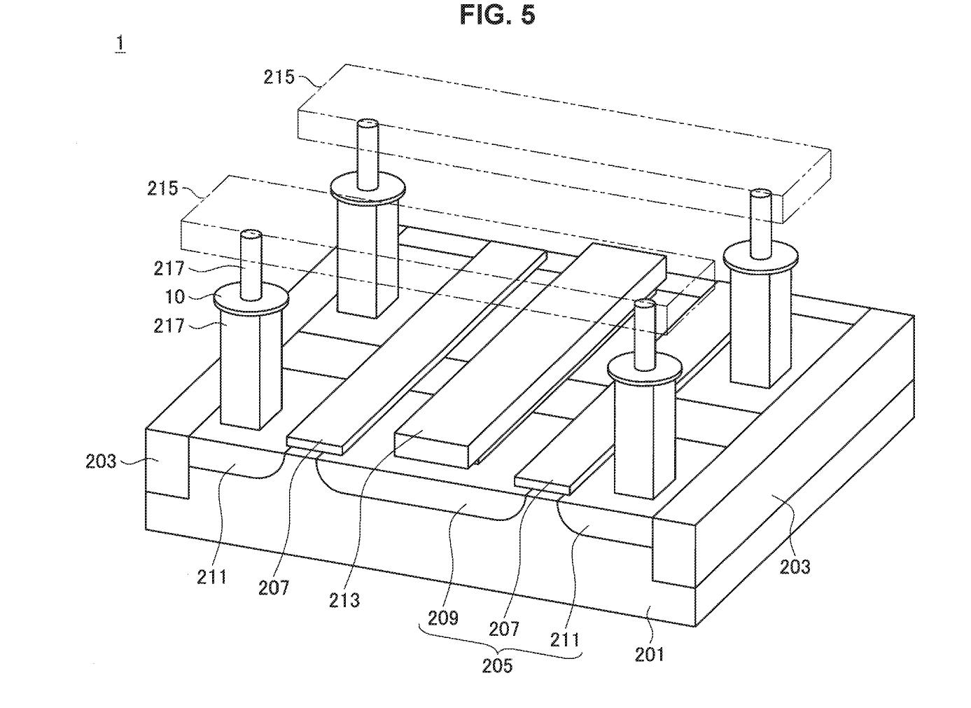

FIG. 4 is a diagram for describing the TMR effect of the magnetoresistive element 321 having the general dual MTJ structure. In FIG. 4, only the portion corresponding to the dual MTJ structure (the lower magnetization fixed layer 325, the lower tunnel barrier layer 327, the storage layer 329, the upper tunnel barrier layer 331, and the upper magnetization fixed layer 333) of the magnetoresistive element 321 illustrated in FIG. 3 is illustrated, and magnetization directions of the lower magnetization fixed layer 325, the storage layer 329, and the upper magnetization fixed layer 333 are simulatively indicated by upward and downward arrows beside the layers.

As illustrated, in the magnetoresistive element 321, the lower magnetization fixed layer 325 and the upper magnetization fixed layer 333 have the opposite magnetization directions to each other. Thus, when the lower magnetization fixed layer 325 and the storage layer 329 are in the parallel state, the upper magnetization fixed layer 333 and the storage layer 329 are in the anti-parallel state (“arrangement (1)” in the drawing). At this time, while an electric resistance of the lower tunnel barrier layer 327 is low, an electric resistance of the upper tunnel barrier layer 331 is high, and thus the resistances cancel each other.

On the other hand, when the lower magnetization fixed layer 325 and the storage layer 329 are in the anti-parallel state, the upper magnetization fixed layer 333 and the storage layer 329 are in the parallel state (“arrangement (2)” in the drawing). At this time, while an electric resistance of the lower tunnel barrier layer 327 is high, an electric resistance of the upper tunnel barrier layer is low, and thus the resistances cancel each other. As a result, in the magnetoresistive element 321, a change in electric resistance between “arrangement (1)” and “arrangement (2),” which are states indicating “1” or “0,” respectively, is small.

As a technology to solve this problem of the magnetoresistive element 321 having the dual MTJ structure, the technology disclosed in Patent Literature 1 has been proposed. Specifically, Patent Literature 1 discloses a magnetoresistive element having the dual MTJ structure in which a film thickness of the tunnel barrier layer arranged on a lower side among two tunnel barrier layers is configured to be thicker than a film thickness of the tunnel barrier layer arranged on an upper side. In Patent Literature 1, for example, the tunnel barrier layers are formed using MgO, the film thickness of the tunnel barrier layer arranged on the lower side is set to be 0.8 nm to 1.5 nm, and the film thickness of the tunnel barrier layer arranged on the upper side is set to be 0.5 nm to 1.0 nm. According to this configuration, the TMR effect of the thinned tunnel barrier layer decreases, and thus a magnetoresistance change ratio of the whole element is considered to increase.

However, when the tunnel barrier layer is thinned, a defect such as a pinhole occurs in the tunnel barrier layer resulting from the thinning, and thus there is concern of a dielectric breakdown voltage significantly decreasing. That is, when the tunnel barrier layer is thinned, there is concern of a withstand voltage of the element being lower and reliability of the element being significantly impaired. Therefore, thinning the tunnel barrier layer is not favorable in terms of reliability.

The examination result of the general existing MTJ element by the present inventors has been described above. In the general existing MTJ element, particularly the magnetoresistive element having the dual MTJ structure, a technology that can increase a magnetoresistance change ratio of a whole element while maintaining a film thickness of a tunnel barrier layer as described above has been demanded. If a magnetoresistance change ratio of a whole element can be increased while a film thickness of a tunnel barrier layer is maintained, a magnetoresistive element having the dual MTJ structure with high reliability and higher performance can be realized. In addition, if an ST-MRAM is configured using such a magnetoresistive element, a storage device (memory element) with lower power consumption and a larger capacity can be realized.

Taking the above circumstances into consideration, the present inventors have conceived the present disclosure as a result of intensive study on a technology for a magnetoresistive element having the dual MTJ structure in which a magnetoresistance change ratio of the whole element can be increased while a film thickness of a tunnel barrier layer is maintained. Preferred embodiments of the present disclosure conceived by the present inventors will be described below.

### (2. Configuration of Storage Device)

FIG. 5 is a perspective view illustrating a schematic configuration of a storage device according to an embodiment of the present disclosure. In FIG. 5, only a part of the storage device according to the present embodiment is extracted and schematically illustrated.

As illustrated in FIG. 5, the storage device 1 according to the present embodiment is configured such that magnetoresistive elements 10 that function as storage element that can retain information depending on a magnetization state are arranged near the intersections of two kinds of address wiring (e.g., a word line and a bit line) that are orthogonal to each other.

Specifically, in the storage device 1, a gate electrode 207, a drain region 209, and a source region 211 constituting a select transistor 205 for selecting each magnetoresistive element 10 are each formed in a portion of a semiconductor substrate 201 such as a silicon substrate separated by element separation layers 203. In the illustrated example, one memory cell is constituted by one magnetoresistive element 10 and one select transistor 205 for selecting the magnetoresistive element 10. The storage device 1 is a memory element configured by arranging a plurality of memory cells as described above. In FIG. 5, a portion of the storage device 1 corresponding to four memory cells is extracted and illustrated.

The gate electrode 207 extends in the depth direction of the drawing and also serves as one address wiring (a word line). Wiring 213 is connected to the drain region 209, and the drain region 209 is configured to be capable of appropriately changing its electric potential via the wiring 213. Note that, in the illustrated example, the drain region 209 is formed to be shared by select transistors 205 arranged next to each other.

The magnetoresistive element 10 is arranged above the source region 211. Furthermore, a bit line 215 that is the other address wiring extends above the magnetoresistive element 10 in a direction orthogonal to the word line (i.e., the gate electrode 207). Contact layers 217 are provided between the source region 211 and the magnetoresistive element 10, and between the magnetoresistive element 10 and the bit line 215 to be electrically connected to each other.

The magnetoresistive element 10 has the dual MTJ structure, and by reversing a magnetization direction of a storage layer of the magnetoresistive element 10 using spin torque magnetization reversal, information of 1/0 can be recorded into the magnetoresistive element 10. That is, the storage device 1 according to the present embodiment is an ST-MRAM. Note that a specific structure of the magnetoresistive element 10 will be described below.

Specifically, a power supply circuit (not illustrated) that can apply a desired voltage to the gate electrode 207, the wiring 213, and the bit line 215 is provided in the storage device 1. At the time of information writing, the power supply circuit applies a current to address wiring (i.e., the gate electrode 207 and the bit line 215) corresponding to a desired magnetoresistive element 10 into which writing is desired, and thereby a current is caused to flow in the magnetoresistive element 10. At this time, electric potentials of the address wiring and the wiring 213 connected to the drain region 209 are appropriately adjusted so that the current flowing in the magnetoresistive element 10 is greater than a reverse current. Accordingly, the magnetization direction of the storage layer of the magnetoresistive element 10 is reversed, and thus information can be written in the magnetoresistive element 10. Note that, at this moment, by appropriately adjusting an electric potential of the drain region 209 via the wiring 213, the direction of the current flowing in the magnetoresistive element 10 can be controlled, and a direction in which the magnetization direction of the storage layer of the magnetoresistive element 10 is to be changed can be controlled. That is, which information of “1” and “0” is to be written can be controlled.

Meanwhile, at the time of information reading, the power supply circuit applies a current to the gate electrode 207 corresponding to a desired magnetoresistive element 10 from which reading is desired, and the current passing through the magnetoresistive element 10 from the bit line 215 then flowing to the select transistor 205 is detected and compared with a current value of a reference cell. Since electric resistance of the magnetoresistive element 10 changes due to the TMR effect in accordance with a magnetization direction of the storage layer of the magnetoresistive element 10, information of 1/0 can be read on the basis of the magnitude of the detected current value. At this time, since the current at the time of reading is much smaller than the current flowing at the time of writing, the magnetization direction of the storage layer of the magnetoresistive element 10 at the time of reading does not change. That is, in the magnetoresistive element 10, information reading is possible in a non-destructive manner.

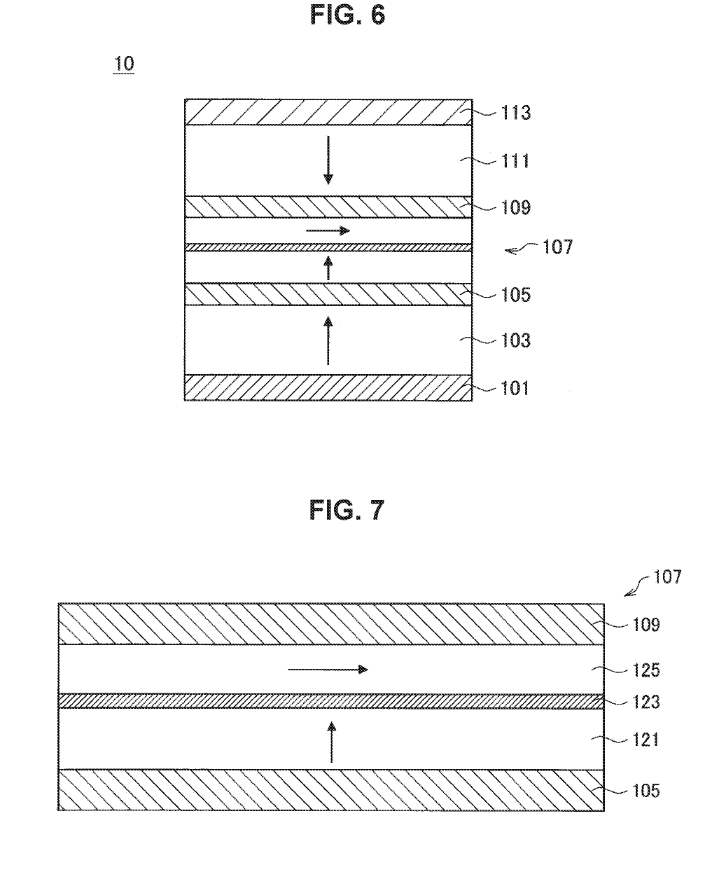

The schematic configuration of the storage device 1 according to the present embodiment has been described above. Note that a configuration of the storage device 1 according to the present embodiment is not limited to the above-described one. As will be described below, the storage device 1 according to the present embodiment has a characteristic configuration in the structure of the magnetoresistive element 10. That is, in the present embodiment, the magnetoresistive element 10 may be configured as illustrated in FIG. 6 and FIG. 7 which will be described below, and other configurations of the storage device 1 may be arbitrary. For example, as the configuration of the storage device 1 except for the magnetoresistive element 10, any of various publicly-known configurations used in general ST-MRAMS may be applied.

In addition, the storage device 1 may be installed in various electric apparatuses in which storage devices can be mounted. The storage device 1 may be mounted in, for example, any of various mobile apparatuses (smartphones, tablet personal computers (PCs), and the like), various electronic apparatuses such as notebook PCs, wearable devices, game apparatuses, music apparatuses, video apparatuses, or digital cameras as a memory for temporary storage or as a storage.

### (3. Structure of Magnetoresistive Element)

FIG. 6 is a cross-sectional view illustrating a schematic configuration of the magnetoresistive element 10 according to the present embodiment illustrated in FIG. 5. FIG. 7 is a cross-sectional view illustrating an enlarged lower tunnel barrier layer, storage layer, and upper tunnel barrier layer extracted from the magnetoresistive element 10 according to the present embodiment illustrated in FIG. 6. Note that, in FIG. 6 and FIG. 7, magnetization directions of layers including a magnetic material are simulatively indicated by arrows for the sake of description.

Referring to FIG. 6, the magnetoresistive element 10 according to the present embodiment is configured in the dual MTJ structure, in which, on a ground layer 101, a lower magnetization fixed layer 103 that is a magnetic material layer having perpendicular magnetic anisotropy of which a magnetization direction is fixed in one direction, a lower tunnel barrier layer 105 including a non-magnetic material, a storage layer 107 including magnetic material layers of which a magnetization direction is reversed due to application of a current in which information is recorded by using reversal of the magnetization direction, an upper tunnel barrier layer 109 including a non-magnetic material, and an upper magnetization fixed layer 111 that is a magnetic material layer having perpendicular magnetic anisotropy of which a magnetization direction is fixed in the opposite direction to that of the lower magnetization fixed layer 103 are laminated. In addition, a cap layer 113 is laminated on the upper magnetization fixed layer 111.

The ground layer 101 plays a role of promoting a smooth and homogeneous granular structure of layers formed thereabove. In addition, the ground layer 101 also plays a role of fixing a magnetization direction of the lower magnetization fixed layer 103 coming in contact with the ground layer 101. To have the function of fixing the magnetization direction of the lower magnetization fixed layer 103, the ground layer 101 is formed using an anti-ferromagnetic material, for example, PtMn, IrMn, or the like in the present embodiment. By providing the anti-ferromagnetic material in contact with the lower magnetization fixed layer 103, a magnetization direction of the lower magnetization fixed layer 103 can be effectively fixed.

Note that the present embodiment is not limited to the example, and as the ground layer 101, any of all materials and configurations applied to magnetoresistive elements having the dual MTJ structure mounted in general ST-MRAMs can be used.

The lower magnetization fixed layer 103 and the upper magnetization fixed layer 111 are layers serving as a reference of a magnetization direction in the magnetoresistive element 10. That is, the magnetoresistive element 10 is configured such that only a magnetization direction of the storage layer 107 is reversed by application of a current, that is, spin injection, and magnetization directions of the lower magnetization fixed layer 103 and the upper magnetization fixed layer 111 are not reversed, and in the magnetoresistive element 10, information of “1” or “0” is defined by relative angles of the magnetization direction of the storage layer 107 and the magnetization directions of the lower magnetization fixed layer 103 and the upper magnetization fixed layer 111. That is, information of 1/0 is recorded due to reversal of the magnetization direction of the storage layer 107.

In the present embodiment, as a magnetic material constituting the lower magnetization fixed layer 103 and the upper magnetization fixed layer 111, a Co—Fe—B alloy is used. In addition, since the lower magnetization fixed layer 103 and the upper magnetization fixed layer 111 serve as a reference of a magnetization direction as described above, their magnetization directions are configured not to change for information writing or reading. However, it is not necessary to completely fix the magnetization directions of the lower magnetization fixed layer 103 and the upper magnetization fixed layer 111 to a specific direction, it is better to make it more difficult to reverse the magnetization directions than a magnetization direction of the storage layer 107. In order to make it more difficult to reverse magnetization directions of the lower magnetization fixed layer 103 and the upper magnetization fixed layer 111 than a magnetization direction of the storage layer 107, a method of, for example, configuring the lower magnetization fixed layer 103 and the upper magnetization fixed layer 111 to have a greater coercive force, to have a greater film thickness, or to have a greater magnetic damping constant than the storage layer 107, or the like can be employed. Alternatively, the lower magnetization fixed layer 103 may be configured in a laminated ferri-structure (which is also called a laminated ferri-pin structure) in which at least two magnetic material layers and a non-magnetic material layer of Ru or the like are laminated. By employing the laminated ferri-structure in the magnetization fixed layer, asymmetry of thermal stability with respect to information writing directions can be cancelled, and stability against spin torque can be improved. Alternatively, the lower magnetization fixed layer 103 may be configured by combining an antiferromagnetic material with the laminated ferri-structure. Accordingly, the magnetization direction can be fixed more effectively. Alternatively, the magnetization direction of the lower magnetization fixed layer 103 may be fixed by appropriately selecting a material and a configuration of the ground layer 101 as described above. As will be described below, the magnetization direction of the upper magnetization fixed layer 111 can be likewise fixed by configuring the cap layer 113 coming in contact with the upper magnetization fixed layer 111 similarly to the ground layer 101.

In addition, the lower magnetization fixed layer 103 and the upper magnetization fixed layer 111 are configured to have perpendicular magnetic anisotropy and such that their magnetization directions are opposite to each other. By configuring the lower magnetization fixed layer 103 and the upper magnetization fixed layer 111 to have perpendicular magnetic anisotropy, the effect of further decreasing a reverse current can be obtained in comparison to a case in which magnetization fixed layers having in-plane magnetic anisotropy are used as described above.

Note that the present embodiment is not limited to the above example. The lower magnetization fixed layer 103 and the upper magnetization fixed layer 111 may have perpendicular magnetic anisotropy and function as reference layers at the time of information writing and reading with respect to the magnetoresistive element 10, and a material and configuration thereof may be arbitrary. For example, as the lower magnetization fixed layer 103 and the upper magnetization fixed layer 111, any of all materials and configurations applied to magnetoresistive elements having the dual MTJ structure mounted in general ST-MRAMs can be used.

The lower tunnel barrier layer 105 and the upper tunnel barrier layer 109 include a non-magnetic material, and function as tunnel barriers at the time of information writing and reading with respect to the magnetoresistive element 10. In the present embodiment, MgO is used as a magnetic material constituting the lower tunnel barrier layer 105 and the upper tunnel barrier layer 109. By using MgO, a magnetoresistance change ratio of a whole element can be increased due to an effect of a coherent tunneling phenomenon. In addition, it is generally known that efficiency of spin injection is dependent on a magnetoresistance change ratio, efficiency of spin injection improves further as a magnetoresistance change ratio becomes higher, and thus a magnetization reversal current density can be reduced. Therefore, by forming the lower tunnel barrier layer 105 and the upper tunnel barrier layer 109 of MgO, a reverse current can be decreased, that is, information can be written at a lower current. In addition, read signal intensity can be increased.

In addition, film thicknesses of the lower tunnel barrier layer 105 and the upper tunnel barrier layer 109 are adjusted so that withstand voltage characteristics can be sufficiently secured. In a case in which the layers are formed using MgO, for example, film thicknesses of the lower tunnel barrier layer 105 and the upper tunnel barrier layer 109 may be about 0.6 nm to 1.5 nm.

However, the present embodiment is not limited to the above example, and as materials of the lower tunnel barrier layer 105 and the upper tunnel barrier layer 109, various materials can be used. For example, the lower tunnel barrier layer 105 and the upper tunnel barrier layer 109 may include any of insulators such as aluminum oxide, aluminum nitride, SiO₂, Bi₂O₃, MgF₂, CaF, SrTiO₂, AlLaO₃, or an Al—N—O alloy, a dielectric, or a semiconductor. In addition, as the lower tunnel barrier layer 105 and the upper tunnel barrier layer 109, any of all materials and configuration applied to magnetoresistive elements having the dual MTJ structure mounted in general ST-MRAMs can be used.

The cap layer 113 is constituted by, for example, a non-magnetic material such as Ru, and has functions of preventing oxidization of the upper magnetization fixed layer 111 and realizing excellent conduction with an upper electrode (not illustrated) formed thereon. Alternatively, the cap layer 113 may be configured similarly to the ground layer 101 in view of fixing a magnetization direction of the upper magnetization fixed layer 111.

However, the present embodiment is not limited to the above example, and as the cap layer 113, any of all materials and configuration applied to magnetoresistive elements having the dual MTJ structure mounted in general ST-MRAMs can be used.

A configuration of the storage layer 107 will be described in detail with reference to FIG. 7. Referring to FIG. 7, the storage layer 107 is configured such that a first magnetic material layer 121, a non-magnetic material layer 123, and a second magnetic material layer 125 are laminated in this order. In the present embodiment, the first magnetic material layer 121 and the second magnetic material layer 125 include a Co—Fe—B alloy, like the lower magnetization fixed layer 103 and the upper magnetization fixed layer 111. In addition, the non-magnetic material layer 123 includes Ta.

However, the present embodiment is not limited to the above example, and materials and configurations of the first magnetic material layer 121, the non-magnetic material layer 123, and the second magnetic material layer 125 may be arbitrary as long as the layers have the characteristics described below. For example, the first magnetic material layer 121 and the second magnetic material layer 125 may be formed using a metal material containing Co, Fe, Ni, or B. Alternatively, for example, the first magnetic material layer 121 and the second magnetic material layer 125 may be formed using an alloy including at least one of Co, Fe, Ni, and B. Alternatively, for example, the first magnetic material layer 121 and the second magnetic material layer 125 may be formed using a material obtained by adding a heterogeneous element to a Co—Fe—B alloy. Accordingly, effects of improved heat resistance resulting from prevention of diffusion, an increase in a magnetoresistance effect, an increase in a dielectric withstand voltage due to flattening, and the like can be obtained. As a material of an additive element of this case, B, C, N, O, F, Li, Mg, Si, P, Ti, V, Cr, Mn, Ni, Cu, Ge, Nb, Ru, Rh, Pd, Ag, Ta, Ir, Pt, Au, Zr, Hf, W, Mo, Re, Os, an alloy thereof, or oxide thereof can be used. In addition, as a material of the non-magnetic material layer 123, Ru, Os, Re, Ir, Au, Ag, Cu, Al, Bi, Si, B, C, Cr, Pd, Pt, Zr, Hf, W, Mo, Nb, V. or an alloy thereof can be used in addition to Ta.

In the present embodiment, it is configured such that, among the first magnetic material layer 121 and the second magnetic material layer 125, the first magnetic material layer 121 has perpendicular magnetic anisotropy, the second magnetic material layer 125 has in-plane magnetic anisotropy. At the time of information writing, a magnetization direction of the first magnetic material layer 121 is reversed in a perpendicular direction, and a magnetization direction of the second magnetic material layer 125 is reversed in an in-plane direction.

Such magnetic anisotropy can be controlled by adjusting compositions of materials constituting the first magnetic material layer 121 and the second magnetic material layer 125 and/or film thicknesses of the first magnetic material layer 121 and the second magnetic material layer 125. For example, a composition of the first magnetic material layer 121 is adjusted so that the magnitude of an effective diamagnetic field that the first magnetic material layer 121 receives is smaller than a saturated magnetization amount Ms. Accordingly, the magnetization direction of the first magnetic material layer 121 can be set to be in the perpendicular direction. In addition, for example, by setting the film thickness of the second magnetic material layer 125 to 0.8 nm in a predetermined composition, the magnetization direction thereof can be set to be in the in-plane direction (also refer to Example 1 which will be described below).

The structure of the magnetoresistive element 10 according to the present embodiment has been described above. Note that the above-described magnetoresistive element 10 can be manufactured by continuously laminating the ground layer 101 to the cap layer 113 in a vacuum device and then appropriately patterning the layers through processing such as etching. As a deposition method and patterning method of each layer, those used in general semiconductor processes can be used, and thus detailed description thereof is omitted.

According to the above-described magnetoresistive element 10, the storage layer 107 is configured such that the first magnetic material layer 121, the non-magnetic material layer 123, and the second magnetic material layer 125 are laminated in this order, the first magnetic material layer 121 has perpendicular magnetic anisotropy, and the second magnetic material layer 125 has in-plane magnetic anisotropy. Accordingly, for example, the TMR effect of the upper tunnel barrier layer 109 positioned between the second magnetic material layer 125 and the upper magnetization fixed layer 111 can be further reduced in comparison to the case in which the storage layer 329 has perpendicular magnetic anisotropy as in the general magnetoresistive element 321 illustrated in FIG. 3. In addition, at this time, unlike the technology disclosed in Patent Literature 1, the effect of reducing the TMR effect can be obtained without thinning the film thickness of the upper tunnel barrier layer 109 (e.g., while maintaining the film thickness of the tunnel barrier layer having a thicker film thickness in the magnetoresistive element disclosed in Patent Literature 1). Therefore, according to the magnetoresistive element 10, without impairing reliability, the magnetoresistance change ratio of the whole element can be increased more than a general magnetoresistive element having the conventional dual MTJ structure.

In addition, according to the magnetoresistive element 10, in order to cause the first magnetic material layer 121 to have perpendicular magnetic anisotropy, the magnitude of the effective diamagnetic field that the first magnetic material layer 121 receives is configured to be smaller than the saturated magnetization amount Ms of the first magnetic material layer 121. Accordingly, the magnitude of an effective diamagnetic field that the storage layer 107 receives is reduced, and thus the magnitude of a reverse current in the storage layer 107 can be reduced. Here, since the magnetoresistive element 10 has the dual MTJ structure, the storage layer 107 can reduce the reverse current more than a magnetoresistive element without the dual MTJ structure because the storage layer receives spin injection from both the lower tunnel barrier layer 105 and the upper tunnel barrier layer 109 more efficiently. That is, according to the present embodiment, in addition to the effect of the reverse current reduction caused by employing the dual MTJ structure, the effect of the reverse current reduction caused by configuring the storage layer 107 as described above can be obtained. Thus, the reverse current can be further reduced in comparison to a general magnetoresistive element having the conventional dual MTJ structure. Therefore, a power consumption amount of the storage device 1 constituted by the magnetoresistive element 10 can be reduced.

Meanwhile, according to the magnetoresistive element 10, since the reverse current can be reduced even without reducing a saturated magnetization amount Ms of the storage layer 107, the storage layer 107 can have a sufficient saturated magnetization amount Ms, and thermal stability of the storage layer 107 can be secured. Furthermore, in the magnetoresistive element 10, the two magnetization fixed layers, that is, the lower magnetization fixed layer 103 and the upper magnetization fixed layer 111, can configure the laminated ferri-pin structure. Accordingly, the lower magnetization fixed layer 103 and the upper magnetization fixed layer 111 can be caused to be blunt with respect to an external magnetic field and a leakage magnetic field caused by the lower magnetization fixed layer 103 and the upper magnetization fixed layer 111 can be blocked. In addition, enhancement of perpendicular magnetic anisotropy of the lower magnetization fixed layer 103 and the upper magnetization fixed layer 111 resulting from interlayer coupling of the plurality of magnetic material layers can be achieved. As described above, according to the magnetoresistive element 10, thermal stability can be sufficiently secured, that is, an information retention ability can be sufficiently secured, and thus the magnetoresistive element 10 excellent in characteristic balance can be configured.

Note that, although the first magnetic material layer 121 positioned on the lower side of the storage layer 107 is set to have perpendicular magnetic anisotropy and the second magnetic material layer 125 positioned on the upper side thereof is set to have in-plane magnetic anisotropy in the above-described configuration example, the present embodiment is not limited thereto. In the present embodiment, one of the two magnetic material layers (the first magnetic material layer 121 and the second magnetic material layer 125) constituting the storage layer 107 may have in-plane magnetic anisotropy, the other one may have perpendicular magnetic anisotropy, and a combination thereof may be arbitrary. For example, contrary to the above-described configuration example, the first magnetic material layer 121 positioned on the lower side may be caused to have in-plane magnetic anisotropy, and the second magnetic material layer 125 positioned on the upper side may be caused to have perpendicular magnetic anisotropy. Also in the configuration, similar effects can be obtained.

In addition, in the present embodiment, one of the two magnetic material layers (the first magnetic material layer 121 and the second magnetic material layer 125) constituting the storage layer 107 may have in-plane magnetic anisotropy, and the other one may have magnetic anisotropy inclined by a predetermined angle at which a perpendicular magnetization dominant state is likely to be maintained from the perpendicular direction (i.e., inclined to the extent that in-plane magnetization does not reach a dominant state). According to this configuration, while the reverse current reduction effect can be reduced, the above-described other effects (i.e., an improved magnetoresistance change ratio and ensured thermal stability) can also be obtained likewise, in comparison to a case with magnetic anisotropy in a completely perpendicular direction.

### Example 1

In order to evaluate magnetic anisotropy of the storage layer 107 of the magnetoresistive element 10 according to the above-described present embodiment, the following experiment has been performed. In the experiment, three types of magnetoresistive element samples having similar configurations to those illustrated in FIG. 6 and FIG. 7 were created, and each of magnetization curves of samples 1 to 3 was measured. Samples 1 to 3 differ only in a film thickness of the second magnetic material layer constituting the storage layer, and other configurations thereof are the same.

Specifically, configurations other than the storage layers of samples 1 to 3 are as follows.

Ground layer: A laminated film of a Ta film having a film thickness of 10 nm and a Ru film having a film thickness of 10 nm.

Lower magnetization fixed layer: A laminated film of a Co—Pt film having a film thickness of 2 nm, a Ru film having a film thickness of 0.7 nm, and a [Co₂₀Fe₈₀]₈₀B₃₀ film having a film thickness of 1.2 nm.

Lower tunnel barrier layer: A magnesium oxide film having a film thickness of 1 nm.

Upper tunnel barrier layer: A magnesium oxide film having a film thickness of 1 nm.

Upper magnetization fixed layer: A laminated film of a [Co₂₀Fe₈₀]₈₀B₃₀ film having a film thickness of 1.3 nm, a Ru film having a film thickness of 0.6 nm, and a Co—Pt film having a film thickness of 2 nm.

Cap layer: A Ta film having a film thickness of 5 nm.

In addition, for the storage layers of samples 1 to 3, a [Co₂₀Fe₈₀]₈₀B₃₀ film having a film thickness 1.3 nm was deposited as a first magnetic material layer, and tantalum having a film thickness of 0.2 nm was deposited as a non-magnetic material layer.

Configurations of second magnetic material layers of the storage layers are as follows.

Sample 1: A [Co₂₀Fe₈₀]₈₀B₃₀ film having a film thickness of 0.6 nm.

Sample 2: A [Co₂₀Fe₈₀]₈₀B₃₀ film having a film thickness of 0.8 nm.

Sample 3: A [Co₂₀Fe₈₀]₈₀B₃₀ film having a film thickness of 1.0 nm.

Each of samples 1 to 3 was produced by forming a thermal oxide film having a thickness of 300 nm on a silicon substrate having a thickness of 0.725 mm, and thereby forming a magnetoresistive element having the above-described configuration thereon. In addition, although detailed description will be omitted, wiring and the like necessary for measurement were also appropriately formed on the silicon substrate.

Each of layers other than insulating layers was deposited using a DC magnetron sputtering method. The insulating layer using oxide was formed by depositing a metal film using an RF magnetron sputtering method or a DC magnetron sputtering method and then performing heat treatment at 350° C. thereon in a heat treatment furnace in a magnetic field.

Magnetization curves of samples 1 to 3 produced as described above were measured through magnetic Kerr effect measurement. At this time, bulk film parts of about 8 mm×8 mm specially provided on silicon substrates for evaluating magnetization curves were used for the measurement, rather than microfabricated elements. In addition, measurement magnetic fields were applied in a perpendicular direction to film surfaces.

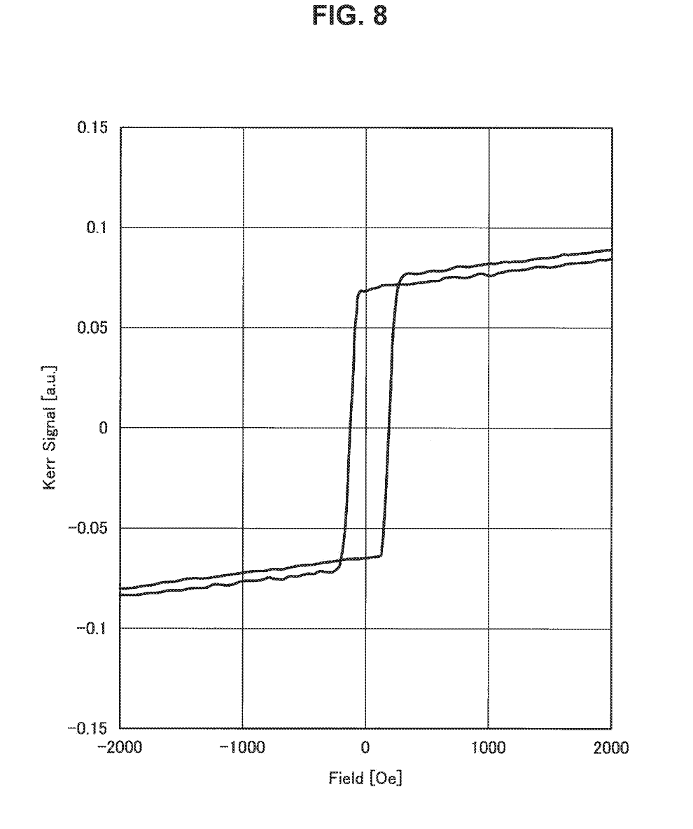

FIG. 8 to FIG. 10 are graphs illustrating measurement results of the magnetization curves of the storage layers of samples 1 to 3, respectively. In FIG. 8 to FIG. 10, the horizontal axes represent applied measurement magnetic field, the vertical axes represent signal value indicating a magnitude of the magnetic Kerr effect, and the relationship of both factors is plotted.

Referring to FIG. 8, it is ascertained that a magnetization curve with high squareness was obtained in sample 1 having the second magnetic material layer of the storage layer with a film thickness of 0.6 nm. This is considered due to the fact that, in sample 1, the first magnetic material layer and the second magnetic material layer of the storage layer are magnetized together in a perpendicular direction.

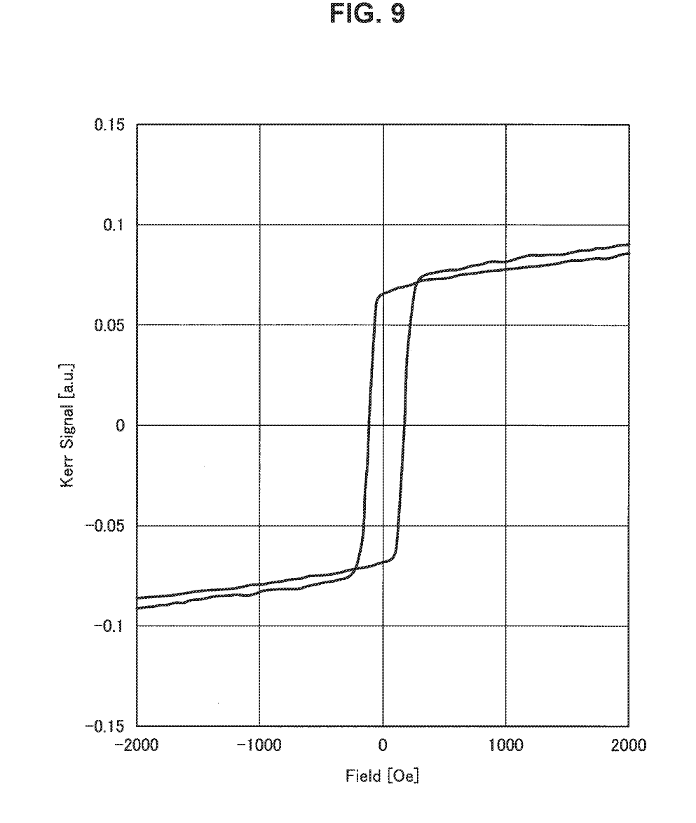

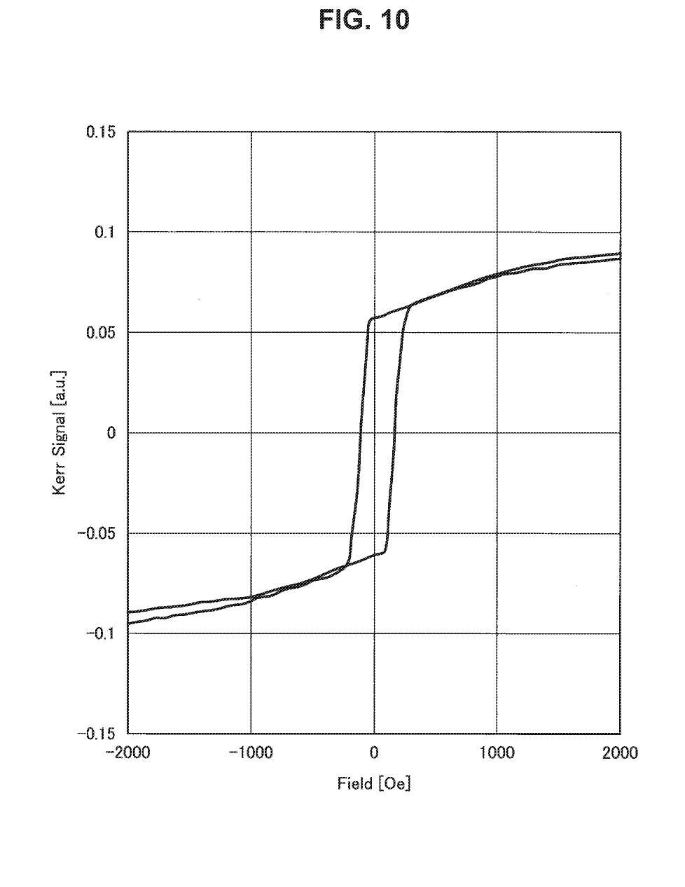

Meanwhile, referring to FIG. 9 and FIG. 10, in samples 2 and 3 having second magnetic material layers of the storage layers with film thicknesses of 0.8 nm and 1.0 nm respectively, changes in squareness of the magnetization curves are found. The changes are considered to be caused due to the fact that, in samples 2 and 3, diamagnetic fields increases as film thicknesses of the second magnetic material layers become thicker, and magnetization directions thereof changes from a perpendicular direction into an in-plane direction. Note that, it is considered that, while the magnetization directions of the second magnetic material layers of the storage layers were oriented toward the in-plane direction, magnetization directions of the first ferromagnetic material layers were perpendicular directions, and thus the magnetization curves illustrated in FIG. 9 and FIG. 10 are considered to have appeared as a result of magnetism of the first magnetic material layers was magnetically coupled with that of the second magnetic material layers via non-magnetic materials inside the storage layers.

The above experiment results indicate that magnetization directions of the second magnetic material layers constituting the storage layers can be controlled in the perpendicular direction or in the in-plane direction by adjusting film thicknesses thereof. In addition, the experiment results indicate that the magnetization directions can be set to the in-plane direction in a case in which the second ferromagnetic material layers are constituted by the [Co₂₀Fe₈₀]₈₀B₃₀ film by setting the film thicknesses to be 0.8 nm or greater. Although the relationship between the film thicknesses and the magnetization directions of the second magnetic material layer were evaluated in the experiment, it is considered that a similar result can also be obtained for the first magnetic material layers.

### Example 2

The following experiment was performed in order to ascertain the effect of improvement in a magnetoresistance change ratio of the magnetoresistive element 10 according to the above-described present embodiment. In the experiment, three types of magnetoresistive element samples having similar configurations to those illustrated in FIG. 6 and FIG. 7 were created, magnetoresistance curves of samples 1 to 3 were measured, and magnetoresistance change ratios were calculated from the magnetoresistance curves.

As samples 1 to 3, samples similar to those of Example 1 described above were used. That is, samples 1 to 3 differ only in a film thickness of the second magnetic material layer constituting the storage layer, and other configurations thereof are the same. On the basis of results of Example 1, it is considered that, in sample 1, magnetization directions of the first magnetic material layer and the second magnetic material layer were a perpendicular direction together, and in samples 2 and 3, the magnetization direction of the first magnetic material layer was a perpendicular direction and the magnetization direction of the second magnetic material layer was an in-plane direction.

Measurement of magnetoresistance change ratios was evaluated using 12-terminal CIPT measurement device. At this time, bulk film parts of about 2 cm square specially provided on silicon substrates for evaluating magnetoresistance change ratios were used for the measurement, rather than microfabricated elements. In addition, measurement magnetic fields were applied in a perpendicular direction to film surfaces. Measurement results of the magnetoresistance change ratios are shown in the following Table 1.

TABLE 1

| | Magnetoresistance |
|---|---|
| | change ratio (%) |
| Sample 1(film thickness of second | 80 |
| magnetic material film = 0.6 nm) | |
| Sample 2(film thickness of second | 95 |
| magnetic material film = 0.8 nm) | |
| Sample 3(film thickness of second | 107 |
| magnetic material film = 1.0 nm) | |

As shown in Table 1, it can be ascertained that the magnetoresistance change ratios of samples 2 and 3 are higher than that of sample 1. The reason for this experiment result is considered that, by increasing the film thicknesses of the second magnetic material layers, the magnetization directions of the second magnetic material layers were changed to the in-plane direction and the TMR effects of the upper tunnel barrier layers decreased, and thus the magnetoresistance change ratios of the whole elements were increased. That is, the experiment result indicates that a reduction in the TMR effect and the effect of improvement in the magnetoresistance change ratio can be surely obtained with the magnetoresistive element 10 according to the present embodiment.

### (4. Supplement)

The preferred embodiment(s) of the present disclosure has/have been described above with reference to the accompanying drawings, whilst the present disclosure is not limited to the above examples. A person skilled in the art may find various alterations and modifications within the scope of the appended claims, and it should be understood that they will naturally come under the technical scope of the present disclosure.

Although the magnetoresistive element 10 is configured as an MTJ element using the TMR effect in the above-described embodiment, for example, the present technology is not limited thereto. For example, layers corresponding to the lower tunnel barrier layer 105 and the upper tunnel barrier layer 109 (which will also be referred to as a first intermediate layer and a second intermediate layer below) of the magnetoresistive element 10 may be formed using a metal material and spin injection may be performed using a giant magnetoresistive (GMR) effect. In this case, as a material of the first intermediate layer and the second intermediate layer, a metal material that exhibits the GMR effect, for example, a metal material containing Cu, Ag, or Cr, an alloy including at least one of Cu, Ag, and Cr, or the like can be used. Alternatively, one of the first intermediate layer and the second intermediate layer may be constituted by a non-magnetic material that exhibits the TMR effect, and the other one may be formed using a metal material that is likely to exhibit the GMR effect.

In addition, although the magnetoresistive element 10 is used as a storage element of a storage device in the above-described embodiment, for example, the present technology is not limited thereto. The magnetoresistive element 10 according to the present embodiment may be applied to other various devices to which a magnetoresistive element can be generally applied, for example, a magnetic head of a hard disk drive (HDD), and the like.

Further, the effects described in this specification are merely illustrative or exemplified effects, and are not limitative. That is, with or in the place of the above effects, the technology according to the present disclosure may achieve other effects that are clear to those skilled in the art from the description of this specification.

Additionally, the present technology may also be configured as below.

(1)

A magnetoresistive element including:

a storage layer of which a magnetization direction is configured to change in accordance with information;

a first magnetization fixed layer configured to be provided below the storage layer and have a magnetization direction perpendicular to a film surface serving as a reference of information stored in the storage layer;

a second magnetization fixed layer configured to be provided above the storage layer and have a magnetization direction that is perpendicular to the film surface serving as a reference of information stored in the storage layer and is opposite to the magnetization direction of the first magnetization fixed layer;

a first intermediate layer configured to be provided between the first magnetization fixed layer and the storage layer; and

a second intermediate layer configured to be provided between the second magnetization fixed layer and the storage layer,

in which the storage layer includes a first magnetic material layer, a non-magnetic material layer, and a second magnetic material layer laminated in that order, and

one of the first magnetic material layer and the second magnetic material layer has a magnetization direction parallel to the film surface.

(2)

The magnetoresistive element according to (1),

in which, among the first magnetic material layer and the second magnetic material layer, a film thickness of the magnetic material layer having the magnetization direction parallel to the film surface is greater than or equal to 0.8 nm.

(3)

The magnetoresistive element according to (1) or (2),

in which the first magnetic material layer and the second magnetic material layer are a metal material containing Co, Fe, Ni, or B, or an alloy including at least one of Co, Fe, Ni, and B.

(4)

The magnetoresistive element according to (2),

in which, among the first magnetic material layer and the second magnetic material layer, at least the magnetic material layer having the magnetization direction parallel to the film surface is a metal material containing Co, Fe, Ni, or B, or an alloy including at least one of Co. Fe, Ni, and B.

(5)

The magnetoresistive element according to any one of (1) to (4).

in which at least one of the first intermediate layer and the second intermediate layer is magnesium oxide.

(6)

The magnetoresistive element according to any one of (1) to (4),

in which at least one of the first intermediate layer and the second intermediate layer is a metal material containing Cu, Ag, or Cr, or an alloy including at least one of Cu, Ag, and Cr.

(7)

The magnetoresistive element according to any one of (1) to (6),

in which a film thickness of the first intermediate layer and the second intermediate layer is 0.6 nm to 1.5 nm.

(8)

A memory element including:

a plurality of magnetoresistive elements configured to retain information in accordance with a magnetization state of a magnetic material; and

wiring configured to apply a current to each of the plurality of magnetoresistive elements in a laminating direction or detect a current flowing in each of the plurality of magnetoresistive elements in the laminating direction,

in which each of the magnetoresistive elements includes
a storage layer of which a magnetization direction is configured to change in accordance with information,
a first magnetization fixed layer configured to be provided below the storage layer and have a magnetization direction perpendicular to a film surface serving as a reference of information stored in the storage layer,
a second magnetization fixed layer configured to be provided above the storage layer and have a magnetization direction that is perpendicular to the film surface serving as a reference of information stored in the storage layer and is opposite to the magnetization direction of the first magnetization fixed layer,
a first intermediate layer configured to be provided between the first magnetization fixed layer and the storage layer, and
a second intermediate layer configured to be provided between the second magnetization fixed layer and the storage layer,

the storage layer includes a first magnetic material layer, a non-magnetic material layer, and a second magnetic material layer laminated in that order, and

one of the first magnetic material layer and the second magnetic material layer has a magnetization direction parallel to the film surface.

(9)

An electronic apparatus including:

a memory element configured to store information,

in which the memory element includes
a plurality of magnetoresistive elements configured to retain information in accordance with a magnetization state of a magnetic material, and
wiring configured to apply a current to each of the plurality of magnetoresistive elements in a laminating direction or detect a current flowing in each of the plurality of magnetoresistive elements in the laminating direction,

each of the magnetoresistive elements includes
a storage layer of which a magnetization direction is configured to change in accordance with information,
a first magnetization fixed layer configured to be provided below the storage layer and have a magnetization direction perpendicular to a film surface serving as a reference of information stored in the storage layer,
a second magnetization fixed layer configured to be provided above the storage layer and have a magnetization direction that is perpendicular to the film surface serving as a reference of information stored in the storage layer and is opposite to the magnetization direction of the first magnetization fixed layer,
a first intermediate layer configured to be provided between the first magnetization fixed layer and the storage layer, and
a second intermediate layer configured to be provided between the second magnetization fixed layer and the storage layer,

the storage layer includes a first magnetic material layer, a non-magnetic material layer, and a second magnetic material layer laminated in that order, and

one of the first magnetic material layer and the second magnetic material layer has a magnetization direction parallel to the film surface.

### REFERENCE SIGNS LIST

1 storage device (memory element)
10, 301, 321 magnetoresistive element
101, 303, 323 ground layer
103, 325 lower magnetization fixed layer
105, 327 lower tunnel barrier layer
107, 309, 329 storage layer
109, 331 upper tunnel barrier layer
111, 333 upper magnetization fixed layer
113, 311, 335 cap layer
121 first magnetic material layer
123 non-magnetic material layer
125 second magnetic material layer
201 semiconductor substrate
203 element separation layer
205 select transistor
207 gate electrode
209 drain region
211 source region
213 wiring
215 bit line
217 contact layer
305 magnetization fixed layer
307 tunnel barrier layer

1. A magnetoresistive element comprising:
a storage layer of which a magnetization direction is configured to change in accordance with information;
a first magnetization fixed layer configured to be provided below the storage layer and have a magnetization direction perpendicular to a film surface serving as a reference of information stored in the storage layer;
a second magnetization fixed layer configured to be provided above the storage layer and have a magnetization direction that is perpendicular to the film surface serving as a reference of information stored in the storage layer and is opposite to the magnetization direction of the first magnetization fixed layer;
a first intermediate layer configured to be provided between the first magnetization fixed layer and the storage layer; and
a second intermediate layer configured to be provided between the second magnetization fixed layer and the storage layer,
wherein the storage layer includes a first magnetic material layer, a non-magnetic material layer, and a second magnetic material layer laminated in that order, and
one of the first magnetic material layer and the second magnetic material layer has a magnetization direction parallel to the film surface.

2. The magnetoresistive element according to claim 1,
wherein, among the first magnetic material layer and the second magnetic material layer, a film thickness of the magnetic material layer having the magnetization direction parallel to the film surface is greater than or equal to 0.8 nm.

3. The magnetoresistive element according to claim 2,
wherein the first magnetic material layer and the second magnetic material layer are a metal material containing Co, Fe, Ni, or B, or an alloy including at least one of Co, Fe, Ni, and B.

4. The magnetoresistive element according to claim 2,
wherein, among the first magnetic material layer and the second magnetic material layer, at least the magnetic material layer having the magnetization direction parallel to the film surface is a metal material containing Co, Fe, Ni, or B, or an alloy including at least one of Co, Fe, Ni, and B.

5. The magnetoresistive element according to claim 1,
wherein at least one of the first intermediate layer and the second intermediate layer is magnesium oxide.

6. The magnetoresistive element according to claim 1,
wherein at least one of the first intermediate layer and the second intermediate layer is a metal material containing Cu, Ag, or Cr, or an alloy including at least one of Cu, Ag, and Cr.

7. The magnetoresistive element according to claim 5,
wherein a film thickness of the first intermediate layer and the second intermediate layer is 0.6 nm to 1.5 nm.

8. A memory element comprising:
a plurality of magnetoresistive elements configured to retain information in accordance with a magnetization state of a magnetic material; and
wiring configured to apply a current to each of the plurality of magnetoresistive elements in a laminating direction or detect a current flowing in each of the plurality of magnetoresistive elements in the laminating direction,
wherein each of the magnetoresistive elements includes
a storage layer of which a magnetization direction is configured to change in accordance with information,
a first magnetization fixed layer configured to be provided below the storage layer and have a magnetization direction perpendicular to a film surface serving as a reference of information stored in the storage layer,
a second magnetization fixed layer configured to be provided above the storage layer and have a magnetization direction that is perpendicular to the film surface serving as a reference of information stored in the storage layer and is opposite to the magnetization direction of the first magnetization fixed layer,
a first intermediate layer configured to be provided between the first magnetization fixed layer and the storage layer, and
a second intermediate layer configured to be provided between the second magnetization fixed layer and the storage layer,
the storage layer includes a first magnetic material layer, a non-magnetic material layer, and a second magnetic material layer laminated in that order, and
one of the first magnetic material layer and the second magnetic material layer has a magnetization direction parallel to the film surface.

9. An electronic apparatus comprising:
a memory element configured to store information,
wherein the memory element includes
a plurality of magnetoresistive elements configured to retain information in accordance with a magnetization state of a magnetic material, and
wiring configured to apply a current to each of the plurality of magnetoresistive elements in a laminating direction or detect a current flowing in each of the plurality of magnetoresistive elements in the laminating direction,
each of the magnetoresistive elements includes
a storage layer of which a magnetization direction is configured to change in accordance with information,
a first magnetization fixed layer configured to be provided below the storage layer and have a magnetization direction perpendicular to a film surface serving as a reference of information stored in the storage layer,
a second magnetization fixed layer configured to be provided above the storage layer and have a magnetization direction that is perpendicular to the film surface serving as a reference of information stored in the storage layer and is opposite to the magnetization direction of the first magnetization fixed layer,
a first intermediate layer configured to be provided between the first magnetization fixed layer and the storage layer, and
a second intermediate layer configured to be provided between the second magnetization fixed layer and the storage layer,
the storage layer includes a first magnetic material layer, a non-magnetic material layer, and a second magnetic material layer laminated in that order, and
one of the first magnetic material layer and the second magnetic material layer has a magnetization direction parallel to the film surface.
